(19) United States
(12) Patent Application Publication
(10) Pub. No.: US 2023/0191519 A1
(43) Pub. Date: Jun. 22, 2023

(54) PRINTING DEVICE AND PRINTING METHOD

(71) Applicant: FUJI ELECTRIC CO., LTD., Kawasaki-shi (JP)

(72) Inventor: Narumi SATO, Matsumoto-city (JP)

(73) Assignee: FUJI ELECTRIC CO., LTD., Kawasaki-shi (JP)

(21) Appl. No.: 17/971,776

(22) Filed: Oct. 24, 2022

(30) Foreign Application Priority Data
Dec. 15, 2021 (JP) 2021-203473

(51) Int. Cl. B23K 3/06; B23K 3/08

(52) U.S. Cl. CPC B23K 3/0638; B23K 3/08; B23K 2101/40

(57) ABSTRACT

To suppress waste of bonding material in a printing device. A printing device includes a dispenser, a squeegee, and a controller. The dispenser individually feeds bonding material to a plurality of apertures formed in a mask. The squeegee moves with an edge portion pressed against the mask and prints the bonding material fed to the apertures from the dispenser on a substrate. The controller drive-controls the dispenser and the squeegee.

### CROSS REFERENCE TO RELATED APPLICATIONS AND INCORPORATION BY REFERENCE

This application claims benefit of priority under 35 USC 119 based on Japanese Patent Application No. 2021-203473 filed on Dec. 15, 2021, the entire contents of which are incorporated by reference herein.

### TECHNICAL FIELD

The present invention relates to a printing device and a printing method.

### BACKGROUND ART

A solder printing system described in PTL 1 has a configuration in which a printing machine and an application device of a dispenser type are unitized and, further, by changing a combination, an inspection unit can be connected and arranged. The solder printing system is also configured such that, based on a result of inspection by the inspection unit, a printing defect of the printing machine can be restored by a dispenser unit.

In a method for applying cream solder described in PTL 2, a screen in which extra-fine pipes are planted in such a manner as to project only on the one surface side is set to face a surface of a substrate on which soldering is required be performed with the pipes separated from the surface by a predetermined distance. In addition, it is configured such that, by pressing cream solder, which is poured out on the upper surface of the screen, by a squeegee, the cream solder is applied, through the pipes, to sites on the substrate at which soldering is required to be performed.

A solder paste feeding device of a screen printing machine described in PTL 3 includes a data accumulation means, which is programmed in a micro-computer. The data accumulation means calculates the amount of fed paste based on a period during which a switch is pressed and the amount of paste to be fed per unit time and stores the calculated amount of fed paste in trial operation result data and, at the same time, stores “the number of produced substrates” of printed circuit substrates, which is acquired from a substrate counting means. When a feeding condition calculation switch is pressed from an operation panel after trial operation is finished, a value obtained by multiplying the n-th “accumulated feed amount” data in the trial operation result data divided by “the number of produced substrates” by a “feeding interval” is stored as a “constant feed amount” .

A printer with a dispenser described in PTL 4 includes a table, a printing mechanism, an image recognition device, and a dispenser. The table supports a substrate in an ascendible and descendible manner between a lower position at which the substrate is transported in and out and an upper position at which, with the upper surface of the substrate in contact with a mask, solder is printed. The printing mechanism includes a squeegee unit and a mask. The image recognition device is supported in such a manner as to be movable in X-Y directions via a movement mechanism within a region sandwiched by the substrate positioned at the lower position and the mask. The dispenser is supported in such a manner as to be movable in X-Y directions in conjunction with the image recognition device via the movement mechanism within a region sandwiched by the substrate positioned at the lower position and the mask.

In a method for cleaning a screen plate described in PTL 5, by advancing a device body along the upper surface of a screen plate, a residue of paste adhering to the upper surface of the screen plate is scraped together by a blade attached to the device body and is adhered to the upper surface of the blade. The blade is rotated and the paste residue adhering to the blade is scraped off by a sliding plate and collected in a collection container, which is positioned immediately below the blade.

A screen printing device described in PTL 6 includes a main-body case, a scraping squeegee, a printing piston, and a squeegee pressurizing piston. The main-body case houses solder paste inside a printing head. The scraping squeegee is arranged in adjacency to the main-body case and scrapes together solder paste from a screen surface. The printing piston pressurizes and pushes out solder paste in the main-body case. The squeegee pressurizing piston operates the scraping squeegee. Solder paste scraped together by the scraping squeegee is collected in the main-body case, and the collected solder paste and solder paste in the main-body case are stirred and mixed.

A method for printing conductor paste described in PTL 7 includes one or both of a step of ink-jet printing and a step of screen printing a conductive wire on a plastic substrate, with the plastic substrate fixed to a fixing jig of an automatic printing device. A conductive mixture includes conductor paste, solvent, and adhesive, and the conductive wire is a bus bar, a grid wire, or an antenna wire of a vehicle.

In a printing device described in PTL 8, the shape of each of printing mask apertures, which is a similar figure to the shape of each of pad electrodes, is tilted with respect to the shape of the pad electrode. Based on this configuration, it is configured such that, even when one surface of a pad electrode is orthogonal to the movement direction of a squeegee due to an arrangement of a substrate and the cross-sectional shape of a terminal of an electronic component to be bonded to the pad electrode, no surface orthogonal to the movement direction of the squeegee is formed on the inner wall surface of each of the printing mask apertures.

### CITATION LIST

### Patent Literature

PTL 1: JP 2006-108200 A
PTL 2: JP 5-347470 A
PTL 3: JP 6-23945 A
PTL 4: JP 3157163 U
PTL 5: JP 11-300941 A
PTL 6: JP 2008-23747 A
PTL 7: JP 2019-504469 A
PTL 8: JP 2006-62117 A

### SUMMARY OF INVENTION

### Technical Problem

Although, as a bonding material, solder is often used, a high-priced sintered material is sometimes chosen from the viewpoint of heat dissipation and long-term reliability. In general screen printing, a substantially larger amount of bonding material than a defined amount of bonding material to be printed on a substrate is required to be fed because bonding material is caused to roll on a mask, and surplus bonding material after printing is discarded and becomes waste. Although there is no problem in discarding low-priced bonding material such as solder, high-priced bonding material, such as sintered material, cannot be easily discarded.

An object of the present invention is to suppress waste of bonding material in a printing device.

### Solution to Problem

A printing device according to one aspect of the present invention includes a feeder, a squeegee, and a control unit. The feeder individually feeds bonding material to a plurality of apertures formed in a mask. The squeegee moves with an edge portion pressed against the mask and prints the bonding material fed to the apertures from the feeder on a substrate. The control unit drive-controls the feeder and the squeegee.

A printing method according to another aspect of the present invention individually feeds bonding material from a feeder to a plurality of apertures formed in a mask. The printing method moves a squeegee with an edge portion of the squeegee pressed against the mask and prints the bonding material fed to the apertures from the feeder on a substrate.

### Advantageous Effects of Invention

According to the present invention, since bonding material is fed to the apertures in the mask directly from the feeder, it becomes unnecessary to cause the bonding material to roll on the mask. Therefore, it is possible to reduce the feed volume of the bonding material compared with general screen printing and suppress waste of the bonding material.

### BRIEF DESCRIPTION OF DRAWINGS

FIG. 1 is a diagram illustrative of a printing device;

FIG. 2 is a flowchart illustrative of printing control processing;

FIG. 3 is a diagram illustrative of feeding of bonding material;

FIG. 4 is a diagram illustrative of printing by a squeegee;

FIG. 5 is a diagram illustrative of collection of bonding material;

FIG. 6 is a diagram illustrative of a substrate from which a mask is removed;

FIG. 7 is a diagram illustrative of return of bonding material;

FIG. 8 is a flowchart illustrative of bonding material feeding processing;

FIG. 9 is a flowchart illustrative of bonding material return processing;

FIG. 10 is a diagram illustrative of a comparative example;

FIG. 11 is a diagram illustrative of a printing device of a second embodiment; and

FIG. 12 is a diagram illustrative of a printing device of a third embodiment.

### DESCRIPTION OF EMBODIMENTS

Hereinafter, embodiments of the present invention are described with reference to the drawings. It should be noted that each drawing is schematic and may not be the same as actual one. Additionally, the embodiments given below exemplify devices and methods for embodying the technological concept of the present invention, and do not limit components of the invention to those below. In other words, various modifications can be added to the technological concept of the present invention without departing from the technological scope described in the appended claims.

### First Embodiment

### Configuration

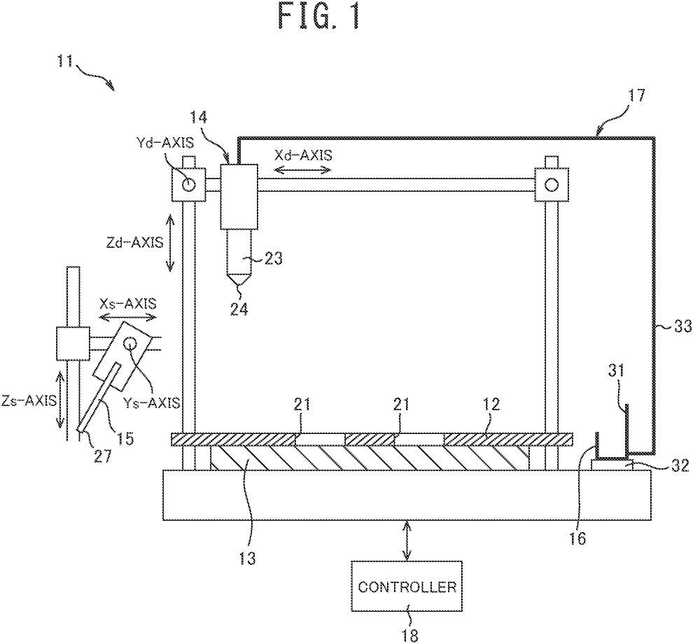

FIG. 1 is a diagram illustrative of a printing device 11.

The printing device 11 is a device for printing (applying) bonding material on a substrate 13, using a mask 12 and includes a dispenser 14 (feeder), a squeegee 15, a collection container 16, a return mechanism 17, and a controller 18 (control unit).

The mask 12 is a jig that is used when bonding material is printed on the substrate 13 and has a plurality of apertures 21, which serve as through-holes penetrating the mask 12 from one surface to the other surface, formed. The mask 12 is formed with a uniform thickness to make flat bonding material to be printed on the substrate 13 as much as possible and has, for example, a thickness of approximately 50 µm to 200 µm. Although the sizes of the apertures 21 differ depending on the sizes of terminals and electrodes of electronic components to be mounted on the substrate 13, it is herein assumed that the apertures 21 are, for example, squares with one side being approximately several mm in plan view. The mask 12 is fixed by a not-illustrated frame.

The substrate 13 is a substrate for a power semiconductor, which operates under high voltage and large current, and is, for example, a direct bonded copper (DCB) substrate, which is fabricated by bonding a copper circuit plate on a ceramic plate. The substrate 13 is fixed on a stage.

As the bonding material, for example, sintered silver material is used. The sintered silver material is paste produced by dispersing silver nanoparticles having surface protective films made of organic substances in organic solvent, and the surface protective films being removed when heated and pressurized causes particles to come into contact with one another, which forms a sintered bonding layer. Since, regarding sintered material using metal nanoparticles, microparticulating the metal to a nanoscale level enables reactivity to be improved and the material to be sintered at a temperature lower than the melting point thereof, it is possible to form a bonding layer having a high melting point, which the metal originally has. In the case of sintered silver material, it is possible to cause the material to sinter at approximately 250 to 300° C. and form a bonding layer having a melting point of approximately 962° C. The sintered silver material has a thermal conductivity substantially higher than that of lead-free solder.

The dispenser 14 includes an attachable/detachable syringe 23, and, at the bottom end of the syringe 23, a discharge port 24 is formed. The dispenser 14 is a component that discharges bonding material from the discharge port 24 of the syringe 23 in response to an air pulse and is movable in three directions along an Xd-axis, a Yd-axis, and a Zd-axis, which are orthogonal to one another, by not-illustrated stepping motors . The bore of the discharge port 24 is smaller than the length of one side of each of the apertures 21 in the mask 12

The squeegee 15 is a flat plate-shaped blade having flexibility and is movable in two directions along an Xs-axis and a Zs-axis, which are orthogonal to each other, and rotatable about a Ys-axis by not-illustrated stepping motors. In FIG. 1, only a portion of the Xs-axis and the Zs-axis is illustrated for descriptive purposes.

The collection container 16 is a container for collecting bonding material adhering to the squeegee 15 and is arranged on the downstream side in a direction in which printing by the squeegee 15 is performed. The collection container 16 has the upper part thereof opened and a receiving surface 31, against which the squeegee 15 is to be rubbed, formed in an upwardly projecting manner on the side far from the mask 12. The receiving surface 31 is a flat surface extending along the Ys-axis direction and the Zs-axis direction. On the under surface of the collection container 16, a weight sensor 32 to measure a collection volume Vc of bonding material collected in the collection container 16 is disposed.

The return mechanism 17 includes a pipe 33 that connects the bottom of the collection container 16 and the dispenser 14, and returns bonding material collected in the collection container 16 to the dispenser 14 by a not-illustrated pump.

The controller 18 includes, for example, a micro-computer and drive-controls the dispenser 14, the squeegee 15, and the return mechanism 17 to perform printing of bonding material on the substrate 13. To the controller 18, data, such as thickness of the mask 12, positions and dimensions of the apertures 21, and feed volumes of bonding materials 35 to the respective apertures 21, are input by a user. In addition, the collection volume Vc detected by the weight sensor 32 and, although illustration is omitted, a planar image of the mask 12 captured by a camera, distance from the discharge port 24 to the substrate 13 detected by a proximity sensor, pressing force of the squeegee detected by a pressure sensor, and the like are also input. The controller 18 performs drive-control of the respective mechanisms, referring to these various types of data.

Next, printing control processing that the controller 18 executes will be described.

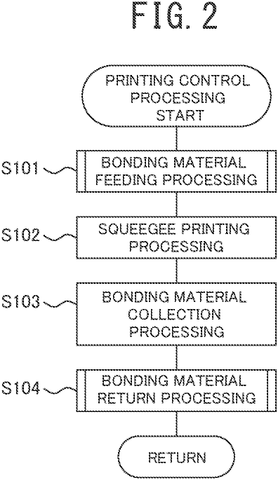

FIG. 2 is a flowchart illustrative of the printing control processing.

In step S101, the controller 18 executes bonding material feeding processing. That is, the controller 18 drive-controls the dispenser 14 to feed bonding material to the plurality of apertures 21 in the mask 12 in sequence.

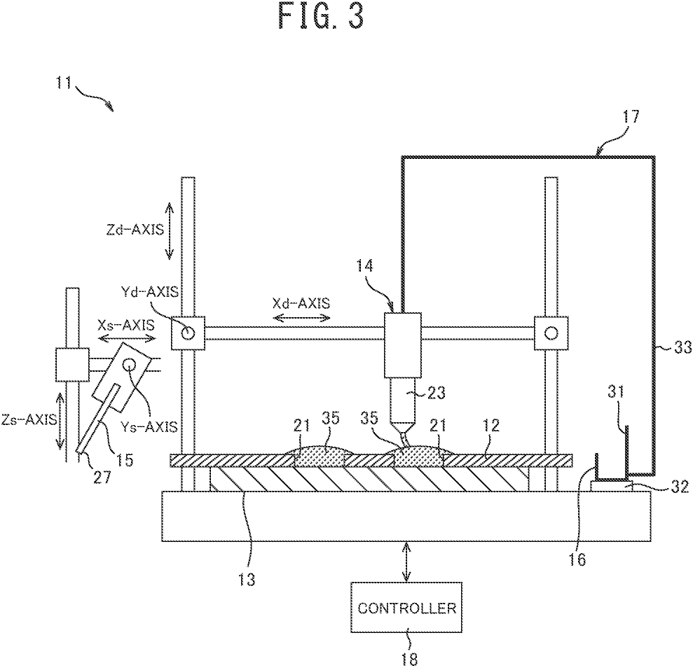

FIG. 3 is a diagram illustrative of feeding of bonding material.

In FIG. 3, the controller 18 causes the squeegee 15 to retreat to an initial position in order to avoid interference with the dispenser 14. The dispenser 14 brings the discharge port 24 close to the apertures 21, moves along the Xd-axis, the Yd-axis, and the Zd-axis while discharging bonding material 35, and thereby successively fills the apertures 21. Although, because of use of the squeegee 15, bonding material of at least a volume exceeding a volume Va of the opened portions of the apertures 21 is required to be fed to the respective apertures 21, a feed volume Vj is set to, for example, two to three times the volume Va in order to suppress waste of the bonding material 35. When feeding of bonding material to all the apertures 21 is finished, the controller 18 causes the dispenser 14 to retreat to the initial position.

Returning to FIG. 2, in succeeding step S102, the controller 18 executes squeegee printing processing. That is, by drive-controlling the squeegee 15 to cause the squeegee 15 to move with an edge portion 27 of the squeegee 15 pressed against the mask 12, the controller 18 prints the bonding material 35 fed to the apertures 21 on the substrate.

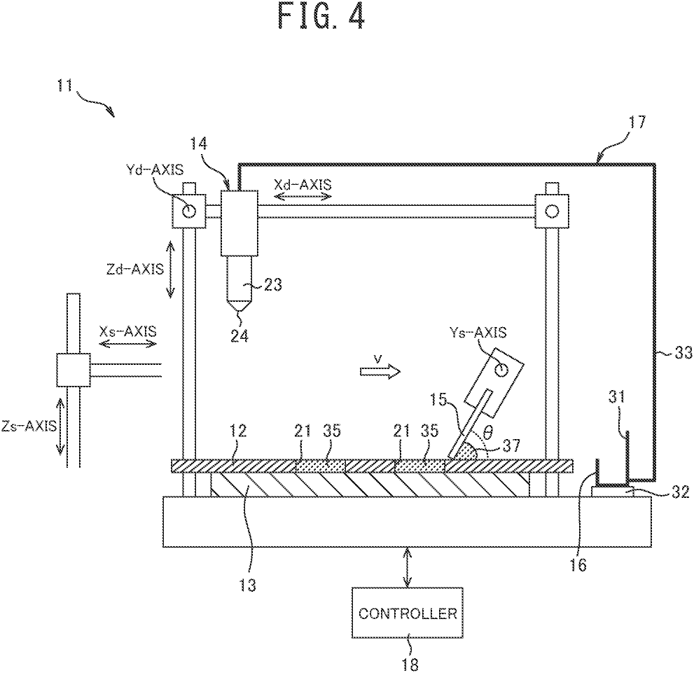

FIG. 4 is a diagram illustrative of printing by the squeegee 15.

The squeegee 15, by moving in the Xs-axis direction while applying downward printing pressure with the edge portion 27 on the bottom end side thereof pressed against the mask 12, successively prints the bonding material fed from the dispenser 14 to the apertures 21 on the substrate 13 and scrapes together surplus bonding material 37 exceeding the volume Va. As a squeegee angle θ with respect to a printing surface as viewed from the Ys-axis direction is made smaller and squeegee velocity v is made slower, filling force to the apertures 21 increases.

Returning to FIG. 2, in succeeding step S103, the controller 18 executes bonding material collection processing. That is, the controller 18 drive-controls the squeegee 15 to collect the bonding material 37, which is scraped together by the squeegee 15, in the collection container 16.

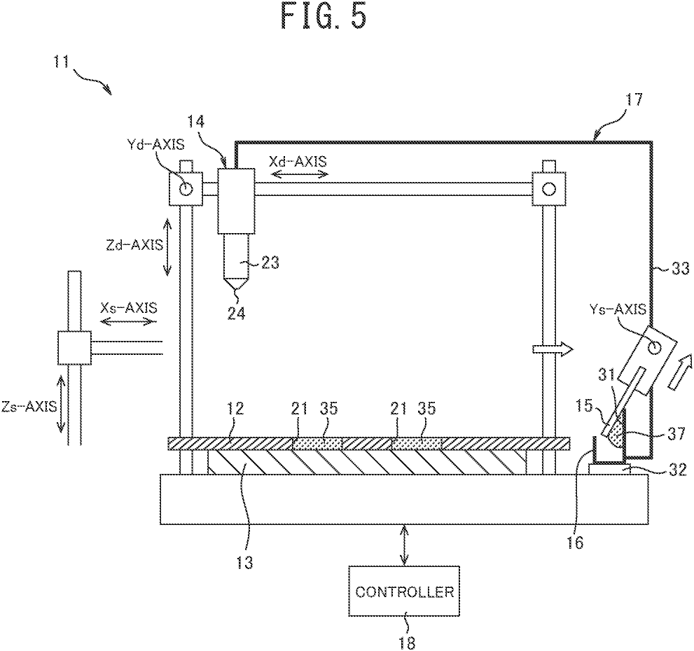

FIG. 5 is a diagram illustrative of collection of the bonding material 37.

The squeegee 15 moves along the Xs-axis until coming into contact with the receiving surface 31 and, subsequently, by moving obliquely upward in accordance with the squeegee angle θ, rubs the scraped bonding material 37 against the receiving surface 31 and transfers the bonding material 37 to the receiving surface 31. The high-viscosity bonding material 37 adheres to the receiving surface 31. When the collection of the scraped bonding material 37 is finished, the controller 18 causes the squeegee 15 to retreat to the initial position.

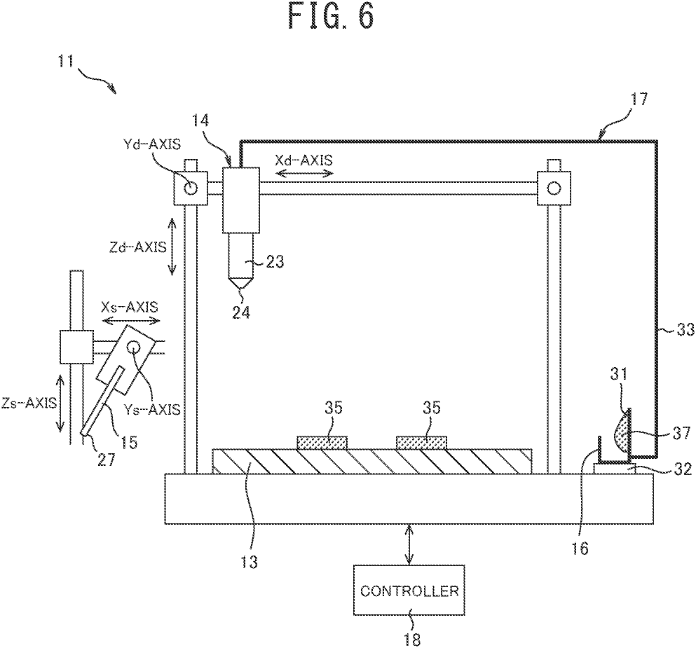

FIG. 6 is a diagram illustrative of the substrate 13 from which the mask 12 is removed.

When the mask 12 is removed, the substrate 13 is brought to a state in which the bonding materials 35 are printed at predetermined positions on the substrate 13. The bonding materials 35 printed on the substrate 13 have upper surfaces thereof made flat by the squeegee 15. The substrate 13 on which the bonding materials 35 are printed is transported to a further downstream step, and mounting electronic components while heating and pressurizing the bonding material causes bonding of the substrate 13 and the electronic components to be performed through sintering of the sintered material. When the printed substrate 13 is transported to a downstream step, a new substrate 13 is set on the stage, the mask 12 is set on the substrate 13, and printing is performed as described afore.

Returning to FIG. 2, in succeeding step S104, the controller 18 executes bonding material return processing. That is, the controller 18 drives the return mechanism 17 as needed and thereby returns the collected bonding material 37 to the dispenser 14, and subsequently returns to a predetermined main program.

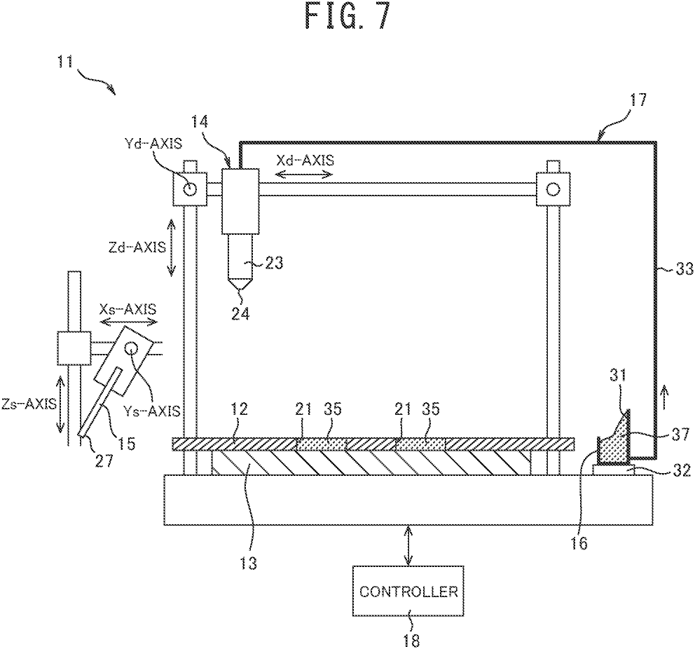

FIG. 7 is a diagram illustrative of return of the bonding material 37.

When the collection of the bonding material 37 is repeated, the bonding material 37 adhering to the receiving surface 31 increases, and the bonding material 37, falling by self-weight or pushed by the squeegee 15, accumulates on the bottom of the collection container 16. Note that the controller 18 may accelerate the fall of the bonding material 37 by self-weight by vibrating the receiving surface 31 with ultrasonic waves. By, when some amount of bonding material 37 has accumulated, sucking the bonding material 37 from the bottom of the collection container 16 and discharging the sucked bonding material 37 to the dispenser 14 via the pipe 33, the collected bonding material 37 is reused.

Next, a subroutine of the bonding material feeding processing, which is executed in step S101, will be described.

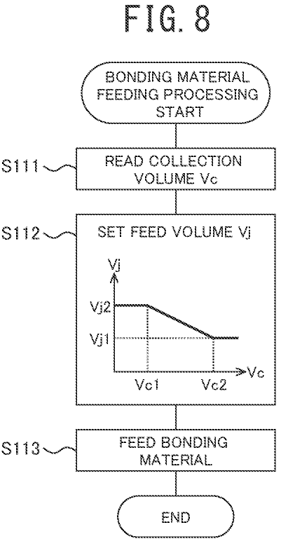

FIG. 8 is a flowchart illustrative of the bonding material feeding processing.

In step S111, the the controller 18 reads a collection volume Vc of the bonding material 37.

In succeeding step S112, the controller 18, referring to a setting map, sets a feed volume Vj to the respective apertures 21 according to the collection volume Vc. The setting map has the collection volume Vc as the abscissa and the feed volume Vj as the ordinate, as illustrated in the drawing. For the collection volume Vc, a predetermined value Vc1 and value Vc2 are defined, where the value Vc2 is greater than the value Vc1. For the feed volume Vj , a predetermined value Vj1 and value Vj2 are defined, where the value Vj2 is greater than the value Vj1. The value Vj1 is, for example, a value approximately two times the volume Va in the apertures 21, and the value Vj2 is, for example, a value approximately three times the volume Va in the apertures 21. In this setting, when the collection volume Vc is less than or equal to the value Vc1, the feed volume Vj is maintained at the value Vj2. In addition, when the collection volume Vc is within a range greater than the value Vc1 and less than the value Vc2, the greater the collection volume Vc is, the smaller the feed volume Vj becomes within a range greater than the value Vj1 and less than the value Vj2. Further, when the collection volume Vc is greater than or equal to the value Vc2, the feed volume Vj is maintained at the value Vj1.

In succeeding step S113, the controller 18 feeds bonding material to the apertures 21 in sequence in accordance with the set feed volume Vj and subsequently terminates the bonding material feeding processing.

Next, a subroutine of the bonding material return processing, which is executed in step S104, will be described.

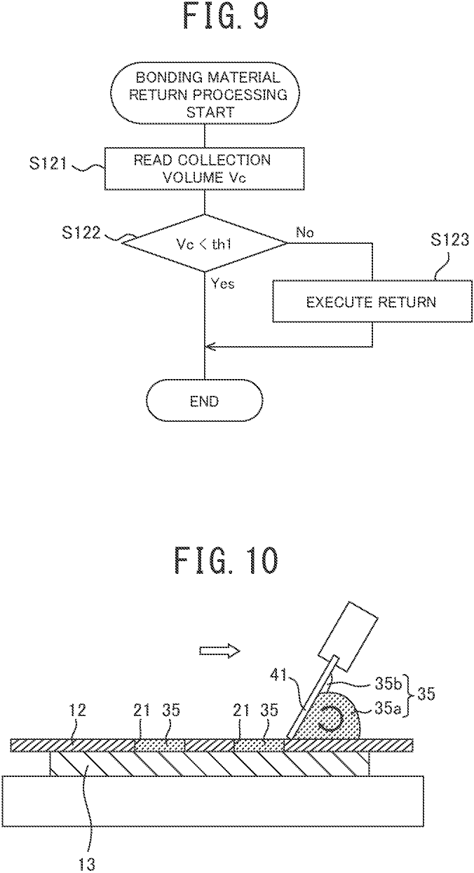

FIG. 9 is a flowchart illustrative of the bonding material return processing.

In step S121, the the controller 18 reads the collection volume Vc of the bonding material 37.

In succeeding step S122, the controller 18 determines whether or not the collection volume Vc is less than a predetermined threshold value th1. When the collection volume Vc is less than the threshold value th1, the controller 18 determines that return of the bonding material 37 is unnecessary and terminates the bonding material return processing. In contrast, when the collection volume Vc is greater than or equal to the threshold value th1, the controller 18 determines that return of the bonding material 37 is necessary and transitions to step S123.

In step S123, the controller 18 executes return of the bonding material 37 and subsequently terminates the bonding material return processing. Although, in this example, the pump is driven for a fixed duration, the driving time of the pump may be made variable according to the collection volume Vc of the bonding material 37.

### Advantageous Effects

Next, major advantageous effects of the first embodiment will be described.

The printing device 11 includes the dispenser 14, the squeegee 15, and the controller 18. The dispenser 14 individually feeds the bonding material 35 to the plurality of apertures 21 formed in the mask 12. The squeegee 15 moves with the edge portion 27 thereof pressed against the mask 12 and prints the bonding material 35 fed to the apertures 21 from the dispenser 14 on the substrate 13. The controller 18 drive-controls the dispenser 14 and the squeegee 15. Since, as described above, the bonding material 35 is fed to the apertures 21 in the mask 12 directly from the dispenser 14, it becomes unnecessary to cause the bonding material 35 to roll on the mask 12. Therefore, it is possible to reduce the feed volume Vj of the bonding material 35 compared with general screen printing and suppress waste of the bonding material 35.

The bonding material 35 is a sintered material. Since sintered material can be sintered at a temperature lower than the melting point, it is possible to form a bonding layer that excels in heat resistance. Therefore, sintered material is suitable for the substrate 13 that is required to operate at high temperature. Since, among metals, sintered silver material in particular has a higher thermal conductivity than solder, the sintered silver material excels in heat dissipation and long-term reliability.

The dispenser 14 includes the discharge port 24, which is formed smaller than each of the apertures 21 and discharges the bonding material 35. Because of this configuration, it is possible to, when the bonding material 35 is fed to the apertures 21, secure a vent path for air and thereby facilitate filling of the apertures 21 with the bonding material 35.

The printing device 11 includes the collection container 16 and the return mechanism 17. The collection container 16 collects the bonding material 37 scraped together by the squeegee 15. The return mechanism 17, drive-controlled by the controller 18, returns the bonding material 37 collected in the collection container 16 to the dispenser 14. Because of this configuration, it is possible to reuse the scraped bonding material 37 and suppress waste of the bonding material 37.

The collection container 16 is arranged on the downstream side in the direction in which printing by the squeegee 15 is performed and includes the receiving surface 31 against which the squeegee 15 is rubbed. Because of this configuration, it is possible to smoothly transitions from the printing processing by the squeegee 15 to the collection processing of the bonding material 37.

When the collection volume Vc of the bonding material 37 collected in the collection container 16 becomes greater than or equal to the predetermined threshold value th1, the controller 18 returns the bonding material 37 collected in the collection container 16 to the dispenser 14. Because of this configuration, it is possible to return the bonding material 37 to the dispenser 14 at an appropriate timing and prevent the return mechanism 17 from being unnecessarily driven.

As the collection volume Vc of the bonding material 37 collected in the collection container 16 is larger, the controller 18 reduces the feed volume Vj of the bonding material 35 to be fed to the apertures 21 to a lower volume. Because of this configuration, it is possible to suppress waste of the bonding material 35.

A printing method individually feeds the bonding material 35 to the plurality of apertures 21 formed in the mask 12 from the dispenser 14. The printing method causes the squeegee 15 to move with the edge portion 27 of the squeegee 15 pressed against the mask 12 and prints the bonding material 35 fed to the apertures 21 on the substrate 13. Since, as described above, the bonding material 35 is fed to the apertures 21 in the mask 12 directly from the dispenser 14, it becomes unnecessary to cause the bonding material 35 to roll on the mask 12. Therefore, it is possible to reduce the feed volume Vj of the bonding material 35 compared with general screen printing and suppress waste of the bonding material 35.

Next, a comparative example will be described.

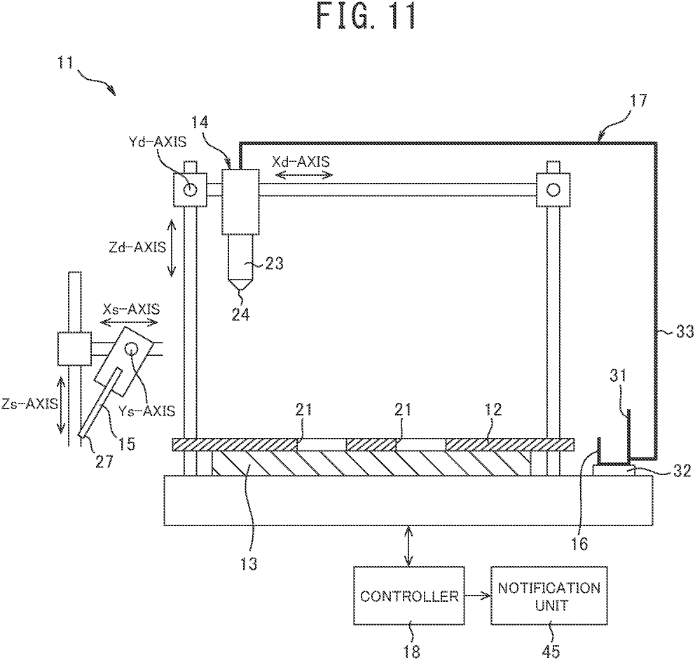

FIG. 10 is a diagram illustrative of the comparative example.

Since the comparative example is a printing device that performs general screen printing and is the same as the first embodiment except performing printing by a squeegee 41 while causing a bonding material 35 to roll, the same reference signs are assigned to constituent elements common to the first embodiment and detailed description thereof will be omitted.

In the general screen printing, in order to perform printing while stirring the bonding material 35, it is necessary to, when the squeegee 41 is moved along the Xs-axis, cause the bonding material 35 to roll on a mask 12 in such a way that the bonding material 35 rolls in the moving direction of the squeegee 41. Because of this configuration, it is possible to keep the bonding material 35 in uniform characteristics and stabilize printing quality.

Since a certain volume of bonding material 35a is needed as a portion of the bonding material 35 to be caused to roll and, in addition thereto, the bonding material 35 includes bonding material 35b as a portion adhering to the squeegee 41, a great volume of bonding material 35 needs to exist between the squeegee 41 and the mask 12. That is, although it is only required to finally print approximately several hundred milligrams to several tens of grams of bonding material 35 on the substrate 13, a great volume of bonding material 35 substantially exceeding the volume to be printed is to be fed between the squeegee 41 and the mask 12. Specifically, approximately several grams to more than ten grams of bonding material 35 per cm of width of the squeegee 41 are required to be fed. Further, the bonding material 35 having been fed on the mask 12 needs to be used up within several hours because the bonding material 35 deteriorates every moment, and the bonding material 35 that is left unused after expiration of the time limit becomes waste because such bonding material 35 cannot be reused and is discarded. Although there is no problem in discarding low-priced bonding material, such as solder, high-priced bonding material 35, such as sintered material, cannot be easily discarded, and a method that does not produce waste has been expected.

### Second Embodiment

### Configuration

A second embodiment is an embodiment in which, with respect to bonding material 37 collected in a collection container 16, elapsed time t since the bonding material 37 was fed by a dispenser 14 is notified. Since the second embodiment is the same as the afore-described first embodiment except this feature, the same reference signs are assigned to constituent elements common to the first embodiment and detailed description thereof will be omitted.

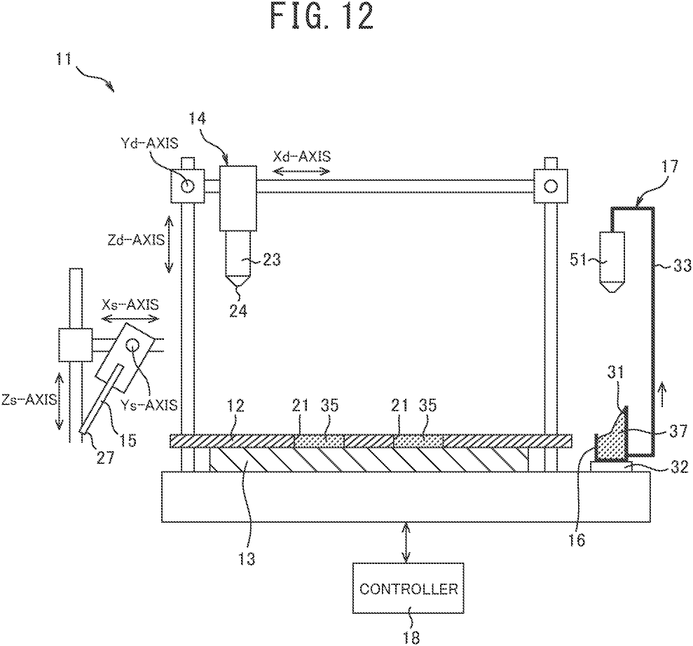

FIG. 11 is a diagram illustrative of a printing device 11 of the second embodiment.

The printing device 11 includes a notification unit 45. The notification unit 45 is, for example, a display. A controller 18 drive-controls the notification unit 45 to notify, with respect to the bonding material 37 collected in the collection container 16, elapsed time t since the bonding material 37 was fed by the dispenser 14, by display. It is assumed that the elapsed time t is time since a portion of the bonding material 37 that has been fed from the same syringe 23 and collected was first discharged from the syringe 23.

### Advantageous Effects

Next, major advantageous effects of the second embodiment will be described.

The printing device 11 includes the notification unit 45. The notification unit 45, drive-controlled by the controller 18, notifies, with respect to the bonding material 37 collected in the collection container 16, elapsed time t since the bonding material 37 was fed by the dispenser 14. Because of this configuration, it is possible to cause a user to be aware of a time limit on the use of the collected bonding material 37 and help the user in determining whether to reuse or discard the bonding material 37. That is, since the collected bonding material 37 is required to be used up within several hours because the bonding material 37 deteriorates every moment, notifying the user of the elapsed time t is meaningful and leads to urging the user to take an appropriate action.

Other advantageous effects are the same as the afore-described first embodiment.

### Variation

Although, in the second embodiment, a configuration in which, with respect to the bonding material 37 collected in the collection container 16, elapsed time t since the bonding material 37 was fed by the dispenser 14 is notified was described, the present invention is not limited thereto. For example, when a time limit on the use of collected bonding material 37 approaches, elapsed time t may be displayed in an emphasized manner. In addition, a user may be notified of the time limit on the use of the bonding material 37 approaching by voice, or, further, feeding of bonding material from the dispenser 14 may be suspended. Because of this configuration, it is possible to cause the user to be surely aware of the time limit on the use of the collected bonding material 37 and urge the user to take a necessary countermeasure.

### Third Embodiment

### Configuration

A third embodiment is an embodiment in which another form of a return mechanism 17 is embodied and an embodiment in which a syringe is used for return of collected bonding material 37. Since the third embodiment is the same as the afore-described first embodiment except this feature, the same reference signs are assigned to constituent elements common to the first embodiment and detailed description thereof will be omitted.

FIG. 12 is a diagram illustrative of a printing device 11 of the third embodiment.

A collection syringe 51 is fixed to a not-illustrated holder. The return mechanism 17 connects the bottom of a collection container 16 and the collection syringe 51 by a pipe 33 and fills the collection syringe 51 with bonding material 37 collected in the collection container 16 by a not-illustrated pump. The collection syringe 51 is mounted on a dispenser 14 manually or automatically after the collection syringe 51 is filled with the bonding material 37. Since the collection syringe 51 is required to be reused as soon as possible, the collection syringe 51 is preferably mounted on the dispenser 14 immediately after the collection syringe 51 is filled, as interrupt processing. A syringe 23 that has been originally mounted on the dispenser 14 is once taken away and, when the collection syringe 51 becomes empty, is mounted on the dispenser 14 again.

### Advantageous Effects

Next, major advantageous effects of the third embodiment will be described.

The dispenser 14 feeds bonding material 35 from the mounted syringe 23, the return mechanism 17 fills the collection syringe 51 with the bonding material 37 collected in the collection container 16, and the collection syringe 51 is mounted on the dispenser 14 after having been filled with the bonding material 37. Because of this configuration, it is possible to reuse the collected bonding material 37 immediately and suppress waste of the bonding material 35.

Other advantageous effects are the same as the afore-described first embodiment.

While the present invention has been described with reference to the limited number of embodiments, the scope of the rights of the invention is not limited thereto. It will be obvious to those skilled in the art that various changes and modifications may be made in the embodiments based on the above disclosure.

REFERENCE SIGNS LIST

| | |
|---|---|
| 11 | Printing device |
| 12 | Mask |
| 13 | Substrate |
| 14 | Dispenser |
| 15 | Squeegee |
| 16 | Collection container |
| 17 | Return mechanism |
| 18 | Controller |
| 21 | Aperture |
| 23 | Syringe |
| 24 | Discharge port |
| 27 | Edge portion |
| 31 | Receiving surface |
| 32 | Weight sensor |
| 33 | Pipe |
| 35 | Bonding material |
| 35 a | Bonding material |
| 35 b | Bonding material |
| 37 | Bonding material |
| 41 | Squeegee |
| 45 | Notification unit |
| 51 | Collection syringe |
| t | Elapsed time |
| th1 | Threshold value |
| v | Squeegee velocity |
| Va | Volume |
| Vc | Collection volume |
| Vj | Feed volume |
| θ | Squeegee angle |

1. A printing device comprising:
a feeder configured to individually feed bonding material to a plurality of apertures formed in a mask;
a squeegee configured to move with an edge portion pressed against the mask and print the bonding material fed to the apertures from the feeder on a substrate; and
a control unit configured to drive-control the feeder and the squeegee.

2. The printing device according to claim 1, wherein the bonding material is a sintered material.

3. The printing device according to claim 1, wherein the feeder includes a discharge port formed smaller than each of the apertures and configured to discharge the bonding material.

4. The printing device according to claim 1 comprising:
a collection container configured to collect the bonding material scraped together by the squeegee; and
a return mechanism drive-controlled by the control unit and configured to return the bonding material collected in the collection container to the feeder.

5. The printing device according to claim 4, wherein the collection container is arranged on a downstream side in a direction in which printing by the squeegee is performed and includes a receiving surface against which the squeegee is rubbed.

6. The printing device according to claim 4, wherein, when a collection volume of the bonding material collected in the collection container is greater than or equal to a predetermined threshold value, the control unit returns the bonding material collected in the collection container to the feeder.

7. The printing device according to claim 4, wherein, as a collection volume of the bonding material collected in the collection container is larger, the control unit reduces a feed volume of the bonding material to be fed to the apertures to a lower volume.

8. The printing device according to claim 4 comprising
a notification unit drive-controlled by the control unit and configured to notify, with respect to the bonding material collected in the collection container, elapsed time since the bonding material is fed by the feeder.

9. The printing device according to claim 4, wherein
the feeder feeds the bonding material from a mounted syringe,
the return mechanism fills a collection syringe with the bonding material collected in the collection container,
and the collection syringe is mounted on the feeder after being filled with the bonding material.

10. A printing method comprising:
individually feeding bonding material to a plurality of apertures formed in a mask from a feeder; and
moving a squeegee with an edge portion of the squeegee pressed against the mask and printing the bonding material fed to the apertures from the feeder on a substrate.

11. The printing device according to claim 2, wherein the feeder includes a discharge port formed smaller than each of the apertures and configured to discharge the bonding material.

12. The printing device according to claim 2 comprising:
a collection container configured to collect the bonding material scraped together by the squeegee; and
a return mechanism drive-controlled by the control unit and configured to return the bonding material collected in the collection container to the feeder.

13. The printing device according to claim 3 comprising:
a collection container configured to collect the bonding material scraped together by the squeegee; and
a return mechanism drive-controlled by the control unit and configured to return the bonding material collected in the collection container to the feeder.

14. The printing device according to claim 5, wherein, when a collection volume of the bonding material collected in the collection container is greater than or equal to a predetermined threshold value, the control unit returns the bonding material collected in the collection container to the feeder.

15. The printing device according to claim 5, wherein, as a collection volume of the bonding material collected in the collection container is larger, the control unit reduces a feed volume of the bonding material to be fed to the apertures to a lower volume.

16. The printing device according to claim 6, wherein, as a collection volume of the bonding material collected in the collection container is larger, the control unit reduces a feed volume of the bonding material to be fed to the apertures to a lower volume.

17. The printing device according to claim 5 comprising
a notification unit drive-controlled by the control unit and configured to notify, with respect to the bonding material collected in the collection container, elapsed time since the bonding material is fed by the feeder.

18. The printing device according to claim 6 comprising
a notification unit drive-controlled by the control unit and configured to notify, with respect to the bonding material collected in the collection container, elapsed time since the bonding material is fed by the feeder.

19. The printing device according to claim 7 comprising
a notification unit drive-controlled by the control unit and configured to notify, with respect to the bonding material collected in the collection container, elapsed time since the bonding material is fed by the feeder.

20. The printing device according to claim 5, wherein
the feeder feeds the bonding material from a mounted syringe,
the return mechanism fills a collection syringe with the bonding material collected in the collection container,
and the collection syringe is mounted on the feeder after being filled with the bonding material.
